(19) United States
(12) Patent Application Publication
(10) Pub. No.: US 2026/0314121 A1
(43) Pub. Date: Oct. 8, 2026

(54) SEMICONDUCTOR DEVICE ARRANGEMENT

(71) Applicant: ENNOSTAR CORPORATION, Hsinchu City (TW)

(72) Inventor: Wei-Yu Chen, Hsinchu City (TW)

(21) Appl. No.: 19/636,125

(22) Filed: Apr. 1, 2026

(30) Foreign Application Priority Data
Apr. 2, 2025 (TW) 114112701

(51) Int. Cl. H10H 20/821; H10H 20/82; H10H 20/85; H10H 29/03; H10H 29/24

(52) U.S. Cl. CPC H10H 20/821; H10H 20/82; H10H 20/8508; H10H 29/03; H10H 29/24

(57) ABSTRACT

A semiconductor device arrangement includes a carrier, an adhesive portion, and a semiconductor device. The carrier has a first surface. The adhesive portion is disposed on the first surface. The semiconductor device is disposed on the adhesive portion and has a second surface. The first surface has a first normal, the second surface has a second normal, and an included angle between the first normal and the second normal is greater than 5 degrees and less than 45 degrees.

### TECHNICAL FIELD

The present disclosure relates to a semiconductor device arrangement, and particularly relates to a semiconductor device arrangement for improving mass-transfer yield.

### CROSS REFERENCE TO RELATED APPLICATION

This application claims the right of priority based on TW Application Serial No. 114112701, filed on April 2, 2025, and the content of which is hereby incorporated by reference in its entirety.

### DESCRIPTION OF BACKGROUND ART

Due to size constraints, semiconductor devices such as light-emitting diodes (LEDs) are difficult to efficiently undergo mass transfer. Accordingly, there remain issues with semiconductor device arrangements that need to be overcome.

### SUMMARY OF THE DISCLOSURE

The present disclosure provides a semiconductor device arrangement. In some embodiments, the semiconductor device arrangement includes a carrier, an adhesive portion, and a semiconductor device. The carrier has a first surface. The adhesive portion is disposed on the first surface. The semiconductor device is disposed on the adhesive portion and has a second surface. The first surface has a first normal, the second surface has a second normal, and an included angle between the first normal and the second normal is greater than 5 degrees and less than 45 degrees.

In other embodiments, the semiconductor device arrangement includes a carrier, an adhesive portion, a plurality of semiconductor devices, and a plurality of connecting portions. The carrier has a first surface. The adhesive portion is disposed on the first surface. The plurality of semiconductor devices is disposed on the adhesive portion, and each of the plurality of semiconductor devices has a second surface. The plurality of connecting portions is disposed on the first surface, and each of the plurality of connecting portions is located between two adjacent ones of the plurality of semiconductor devices. The first surface has a first normal, the second surface has a second normal, and an included angle between the first normal and the second normal is greater than 5 degrees and less than 45 degrees.

### BRIEF DESCRIPTION OF THE DRAWINGS

FIG. 1 shows a schematic cross-sectional view of a semiconductor device arrangement according to some embodiments of the present disclosure.

FIG. 2 shows a schematic cross-sectional view of a semiconductor device arrangement according to other embodiments of the present disclosure.

FIG. 3 shows a schematic top view of a semiconductor device arrangement according to some embodiments of the present disclosure.

FIGS. 4 to 7 show schematic diagrams of a manufacturing process for a semiconductor unit according to some embodiments of the present disclosure.

FIG. 8 shows a schematic top view of the semiconductor unit shown in FIG. 7.

FIG. 9 shows a schematic diagram of a semiconductor device arrangement performing an irradiation process according to some embodiments of the present disclosure.

FIGS. 10 to 12 show schematic diagrams of a manufacturing process for separating a semiconductor device and an adhesive layer according to some embodiments of the present disclosure.

FIGS. 13 and 14 respectively show a schematic top view and a schematic cross-sectional view of a semiconductor unit according to other embodiments of the present disclosure.

FIG. 15 shows a schematic top view of a semiconductor unit according to still other embodiments of the present disclosure.

FIGS. 16 and 17 respectively show a schematic top view and a schematic cross-sectional view of a semiconductor unit according to still other embodiments of the present disclosure.

FIGS. 18 and 19 respectively show a schematic top view and a schematic cross-sectional view of a semiconductor unit according to still other embodiments of the present disclosure.

FIGS. 20 to 27 show schematic top views of semiconductor units according to different embodiments of the present disclosure.

FIGS. 28 and 29 respectively show a schematic top view and a schematic cross-sectional view of a semiconductor unit according to still other embodiments of the present disclosure.

FIG. 30 shows a schematic top view of a semiconductor unit according to still other embodiments of the present disclosure.

FIGS. 31 and 32 shows schematic cross-sectional views of a semiconductor unit according to still other embodiments of the present disclosure.

FIG. 33 shows a schematic top view of a semiconductor unit according to still other embodiments of the present disclosure.

### DETAILED DESCRIPTION OF PREFERRED EMBODIMENTS

In the present disclosure, directional terms such as “on”, “below”, and “between” are intended to describe relative positions among objects and are not intended to limit absolute positions of the objects. In addition, terms “dispose” and “connect” may include situations that two structures are movable or fixed. Furthermore, terms such as “first” and “second” are used to designate different components or to distinguish different embodiments or scopes and are not intended to limit upper or lower bounds on number of the components, nor to limit manufacturing order or placement order of the components.

In some embodiments, directions are not limited to three axes (X, Y, AND z) of Cartesian coordinate system and may be interpreted in a broader sense. For ease of description, a first direction D1 (width direction) corresponds to X-axis direction, a second direction D2 (length direction) corresponds to Y-axis direction, and a third direction D3 (thickness or height direction) corresponds to Z-axis direction. In some embodiments, schematic cross-sectional views in the present disclosure correspond to XZ plane, and schematic top views in the present disclosure correspond to XY plane.

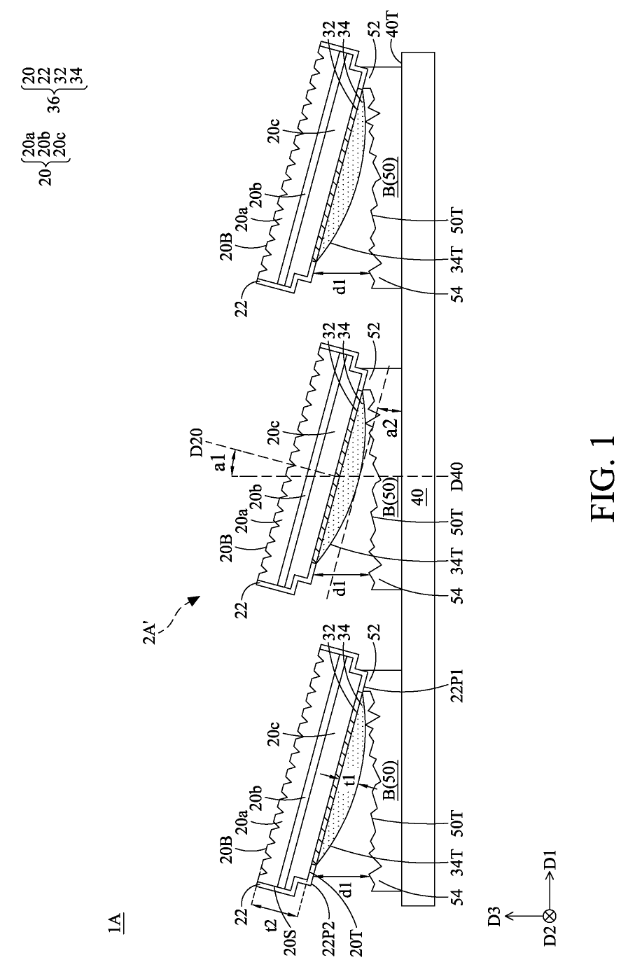

Referring to FIG. 1, FIG. 1 shows a schematic cross-sectional view of a semiconductor device arrangement 1A according to some embodiments of the present disclosure. As shown in FIG. 1, the semiconductor device arrangement 1A includes a carrier 40, an adhesive portion 50, and a semiconductor device 36. In some embodiments, the carrier 40 includes glass, quartz, sapphire, ceramic, polyimide (PI), polycarbonate (PC), polyethylene terephthalate (PET), or polypropylene (PP). In some embodiments, the carrier 40 includes a wafer or a chip.

The adhesive portion 50 is disposed on the carrier 30 and includes a plurality of bodies B. In some embodiments, in the first direction D1 and/or the second direction D2, the plurality of bodies B of the adhesive portion 50 is disposed spaced apart from each other. In some embodiments, the adhesive portion 50 includes epoxy resin, polyethylene terephthalate (PET), or polyimide (PI).

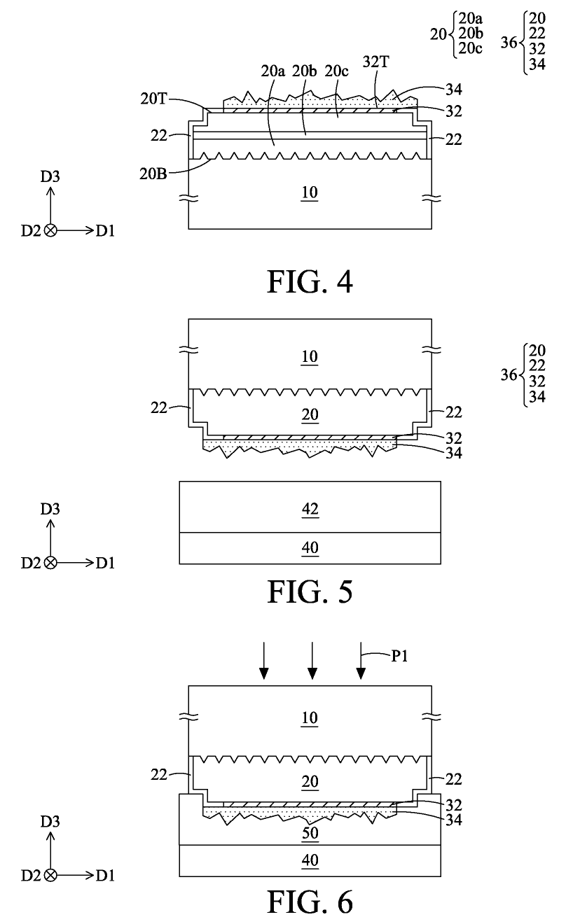

As shown in FIG. 1, semiconductor devices 36 are disposed on the adhesive portion 50, and each semiconductor device 36 is disposed on each of the plurality of bodies B of the adhesive portion 50. The semiconductor device 36 includes a semiconductor stack 20, a protective layer 22, a first conductive layer 32, and a second conductive layer 34. The semiconductor stack 20 includes a first semiconductor layer 20a, an active layer 20b, and a second semiconductor layer 20c, and the active layer 20b is disposed between the first semiconductor layer 20a and the second semiconductor layer 20c. In some embodiments, the first semiconductor layer 20a, the active layer 20b, and the second semiconductor layer 20c may be sequentially formed along a direction of a first axis D20 by an epitaxial growth process (referring to FIG. 4). In some embodiments, the semiconductor device 36 may include a lateral-type semiconductor device, a flip-chip-type semiconductor device, or a vertical-type semiconductor device.

In some embodiments, the first semiconductor layer 20a is a p-type semiconductor layer, and the second semiconductor layer 20c is an n-type semiconductor layer. In other embodiments, the first semiconductor layer 20a is a p-type semiconductor layer, and the second semiconductor layer 20c is an n-type semiconductor layer. The p-type semiconductor layer includes Group II–VI materials or Group III–V materials. The Group II–VI materials include zinc selenide (ZnSe), and the Group III–V materials include gallium nitride (GaN), aluminum nitride (AlN), indium nitride (InN), indium gallium nitride (InGaN), aluminum gallium nitride (AlGaN), or aluminum indium gallium nitride (AlInGaN). In some embodiments, the p-type semiconductor layer includes magnesium (Mg) or carbon (C). In some embodiments, the active layer 20b includes intrinsic semiconductor material, such as indium gallium nitride (InGaN), gallium nitride (GaN), aluminum gallium nitride (AlGaN), or aluminum indium gallium nitride (AlInGaN). In some embodiments, the active layer 20b includes a multiple quantum well (MQW). In some embodiments, the n-type semiconductor layer includes Group II–VI materials or Group III–V materials. In some embodiments, the n-type semiconductor layer includes silicon (Si) or germanium (Ge).

As shown in FIG. 1, the protective layer 22 is disposed on the semiconductor stack 20. In some embodiments, the protective layer 22 covers a part of a surface 20T of the semiconductor stack 20 and exposes another part of the surface 20T. The protective layer 22 optionally covers a side surface 20S of the semiconductor stack 20 and exposes another surface 22B of the semiconductor stack 20. In some embodiments, the protective layer 22 includes electrically insulating materials.

As shown in FIG. 1, the first conductive layer 32 is disposed on the semiconductor stack 20, and the protective layer 22 exposes the first conductive layer 32. In some embodiments, the first conductive layer 32 contacts the protective layer 22. In some embodiments, the second conductive layer 34 is disposed on the first conductive layer 32 and electrically connected to the first conductive layer 32.

The first conductive layer 32 and the second conductive layer 34 include metals, oxides, or semiconductor materials. The metals include tin (Sn), copper (Cu), gold (Au), silver (Ag), nickel (Ni), indium (In), platinum (Pt), palladium (Pd), iridium (Ir), titanium (Ti), chromium (Cr), tungsten (W), aluminum (Al), molybdenum (Mo), magnesium (Mg), zinc (Zn), or alloys thereof. The oxides include transparent conductive oxides (TCOs), such as indium tin oxide (ITO). The semiconductor material includes gallium arsenide (GaAs). In some embodiments, the first conductive layer 32 includes gold (Au), and the second conductive layer 34 includes tin (Sn). In some embodiments, the first conductive layer 32 has a first melting point, the second conductive layer 34 has a second melting point, and the second melting point is less than the first melting point.

As shown in FIG. 1, the protective layer 22 has a first portion 22P1 and a second portion 22P2, and the first portion 22P1 and the second portion 22P2 respectively cover portions of the surface 20T of the semiconductor stack 20. In some embodiments, the second conductive layer 34 contacts the adhesive portion 50. As shown in FIG. 1, the body B of the adhesive portion 50 has a third portion 52 and a fourth portion 52. The first portion 22P1 of the protective layer 22 contacts the third portion 52 of the adhesive portion 50, and the second portion 22P2 of the protective layer 22 is spaced apart from the fourth portion 54 of the adhesive portion 54 by a distance d1. In some embodiments, the second portion 22P2 may contact the adhesive portion 50.

As shown in FIG. 1, in some embodiments, the adhesive portion 50 has a surface 50T located on a side away from the carrier 40. The protective layer 22 and the second conductive layer 34 contacts the surface 50T of the adhesive portion 50. A first contact area A1 is defined between the protective layer 22 and the surface 50T, a second contact area A2 is defined between the second conductive layer 34 and the surface 50T, and the surface 50T has a total surface A3. In some embodiments, a sum of the first contact area A1 and the second contact area A2 is less than 80% of the total area A3. In some embodiments, the sum of the first contact area A1 and the second contact area A2 is greater than 5% of the total area A3. For example, a ratio of the sum of the first contact area A1 and the second contact area A2 to the total area A3 is 0.799, 0.79, 0.75, 0.7, 0.6, 0.5, 0.4, 0.3, or 0.2.

As shown in FIG. 1, the second conductive layer 34 has a protruding surface 34T protruding toward the adhesive portion 50. In some embodiments, in a cross-sectional view, the protruding surface 34T has an arcuate contour, and the surface 50T of the adhesive portion 50 faces the protruding surface 34T. In some embodiments, the protruding surface 34T has a first roughness, the surface 50T of the adhesive portion 50 has a second roughness, and the first roughness is less than the second roughness.

In some embodiments, “roughness” may also be referred to as surface roughness, which is a technical metric representing degree of unevenness of a surface of an object (e.g., the surface 50T of the adhesive portion 50). For example, the roughness may be developed interfacial area ratio (Sdr), arithmetical mean roughness (Ra), ten-point average roughness (Rz), or maximum height (Ry). In some embodiments, the smaller the roughness, the smoother the surface of the object; the larger the roughness, the rougher the surface. In other words, the first roughness of the protruding surface 34T being less than the second roughness of the surface 50T of the adhesive portion 50 indicates that the surface 50T is rougher than the protruding surface 34T.

As shown in FIG. 1, in some embodiments, the second conductive layer 34 has a first thickness t1 between 1µm to 3µm, such as 1µm, 1.5µm, 2µm, 2.5µm, or 3µm. In some embodiments, the semiconductor stack 20 has a second thickness t2, and the first thickness t1 is less than or equal to the second thickness t2.

As shown in FIG. 1, the carrier 40 has a surface 40T, and the adhesive portion 50 is disposed on the surface 40T of the carrier 40, and the adhesive portion 50 is disposed on the surface 40T of the carrier 40. In some embodiments, a normal D40 of the surface 40T extends along the third direction D3. An included angle a1 is defined between the normal D40 and the first axis D20. In some embodiments, the included angle a1 is less than or equal to 45 degrees. In some embodiments, the included angle a1 is greater than or equal to 5 degrees (e.g., between 10 degrees to 35 degrees). In some embodiments, the included angle a1 may be 45 degrees, 40 degrees, 35 degrees, 30 degrees, 25 degrees, or 20 degrees. In some embodiments, the surface 20B of the semiconductor device 36 is perpendicular to the first axis D20. In other words, a normal of the surface 20B corresponds to the first axis D20. In some embodiments, an included angle a2 is defined between a tangent direction at a top of the protruding surface 34T and an extending direction (the first direction D1) of the carrier 40, and the included angle a2 is less than or equal to 45 degrees. In some embodiments, when viewed along direction of the normal D40 (or the third direction D3), an outermost surface of the adhesive portion 50 does not extend beyond an outermost surface of the semiconductor device 36. In other words, when viewed along the direction of the normal D40 (or the third direction D3), a projected area of the adhesive portion 50 on the carrier 40 lies within a projected area of the semiconductor device 36 on the carrier 40.

In some embodiments, the semiconductor device arrangement 1A includes a plurality of semiconductor units 2A’, and each of the plurality of semiconductor units 2A’ includes the carrier 40, the adhesive portion 50, and the semiconductor device 36. In some embodiments, the plurality of semiconductor units 2A’ shares the same carrier 40. In some embodiments, the plurality of semiconductor units 2A’ shares the same adhesive portion 50.

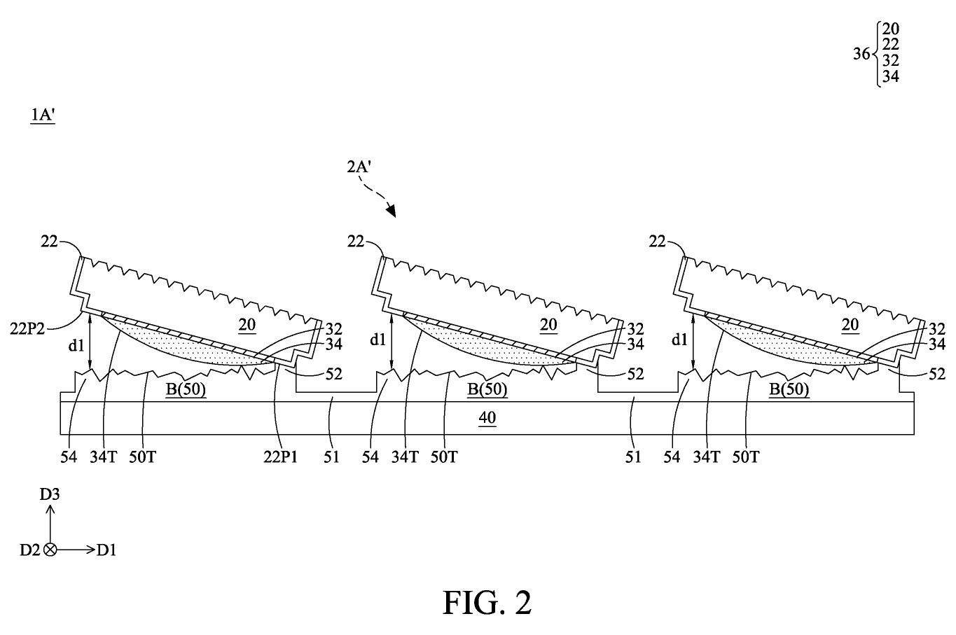

Referring to FIG. 2, FIG. 2 shows a schematic cross-sectional view of a semiconductor device arrangement 1A’ according to other embodiments of the present disclosure. As shown in FIG. 2, in some embodiments, the semiconductor device arrangement 1A’ further includes a plurality of connecting portions 51. Each of the plurality of connecting portions 51 connects two adjacent bodies B of the adhesive portion 50, and the plurality of bodies B of the adhesive portion 50 is continuously disposed on the carrier 40. In some embodiments, each of the plurality of connecting portions 51 is located between two adjacent ones of the plurality of semiconductor units 2A’ or two adjacent semiconductor devices 36. In some embodiments, in the third direction D3, a height of each of the plurality of connecting portions 51 is greater than 0 and lower than heights of the third portion 52 and the fourth portion 54.

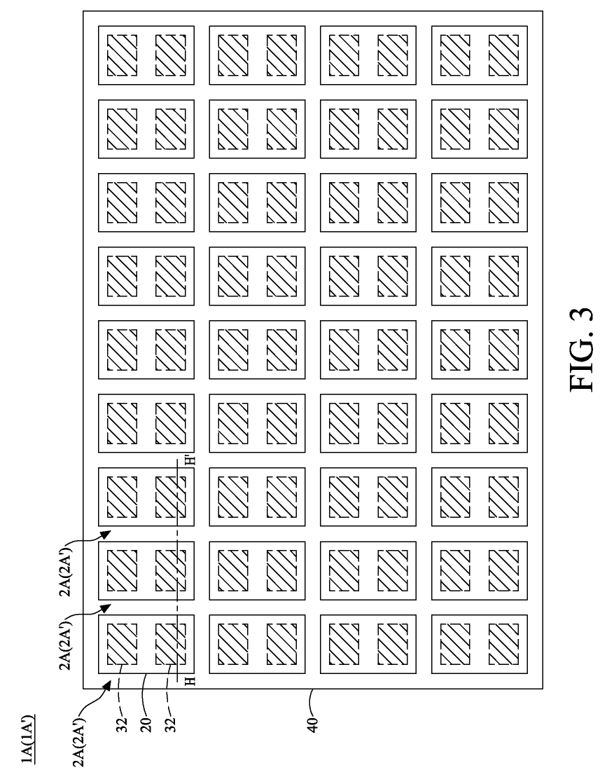

Referring to FIG. 3, FIG. 3 shows a schematic top view of a semiconductor device arrangement 1A or 1A’ according to some embodiments of the present disclosure. In some embodiments, FIG. 1 and FIG. 2 show schematic cross-sectional views taken along line H-H’ shown in FIG. 3. For ease of description, FIG. 3 shows the semiconductor stack 20, the first conductive layer 32, and the carrier 40 of the semiconductor device arrangement 1A or 1A’, and at least the adhesive portion 50 is omitted. As shown in FIG. 3, each of the plurality of semiconductor units 2A’ is arranged spaced apart from one another. In some embodiments, the semiconductor device arrangement 1A or 1A’ includes a plurality of semiconductor devices 36 arranged spaced apart from one another. In some embodiments, each of the plurality of semiconductor devices 36 is a flip chip, and two first conductive layers 32 serve as electrodes of opposite polarity of each of the plurality of semiconductor devices 36 and are located between the semiconductor stack 20 and the carrier 40.

A method for forming the plurality of semiconductor unit 2A is provided. As shown in FIG. 4, first, a substrate 10 is provided. In some embodiments, material of the substrate 10 may refer to material of the carrier 40. Next, the plurality of semiconductor devices 36 is formed on the substrate 10 along the third direction D3. For simplicity, only one semiconductor device 36 is illustrated in FIG. 4 for preparing a semiconductor unit. In some embodiments, the plurality of semiconductor devices 36 is formed on the substrate 10 (e.g., 10, 100, or 1,000 semiconductor devices 36) for preparing a semiconductor device array structure (including a plurality of semiconductor units). In some embodiments, method for forming the plurality of semiconductor devices 36 includes forming the semiconductor stack 20 on the substrate 10 and forming the protective layer 22 on the surface 20T of the semiconductor stack 20. Then, the first conductive layer 32 is formed on the semiconductor stack 20, and the second conductive layer 34 is formed on the surface 32T of the first conductive layer 32. In some embodiments, the substrate 10 is a patterned sapphire substrate (PSS).

Referring to FIG. 5, a carrier 40 is provided, and the adhesive layer 42 is located on the carrier 40. Next, after the structure shown in FIG. 4 is tuned upside down, the semiconductor device 36 is bonded onto the adhesive layer 42. In other words, the semiconductor device 36 is located between the substrate 10 and the carrier 40. In some embodiments, the adhesive layer 42 is flowable (i.e., the adhesive layer 42 is not fully cured).

Referring to FIG. 6, a curing process P1 is performed on the bonded structure to cure the adhesive layer 42 and form the adhesive portion 50. In some embodiments, a portion of the protective layer 22 is exposed from the adhesive portion 50. In other embodiments, the adhesive portion 50 covers a sidewall of the protective layer (not shown). In some embodiments, the substrate 10 extends horizontally beyond the protective layer 22 (not shown), and the adhesive portion 50 extends upward to contact the substrate 10 and the sidewall of the protective layer 22. In some embodiments, the curing process P1 includes a photo-curing process, and the photo-curing process includes irradiating laser light, infrared light, or ultraviolet light.

Referring to FIG. 7, after performing the curing process P1, the substrate 10 is removed to obtain the semiconductor device unit 2A. In some embodiments, an etching process is further included to reduce a width of the adhesive portion 50, thereby making the width of the adhesive portion 50 be less than a width of the semiconductor stack 20. In some embodiments, after the curing process P1, the adhesive portion 50 is located between two adjacent semiconductor stacks 20. In some embodiments, the etching process is configured to thin the adhesive portion 50 to form the plurality of connecting portions 51 as shown in FIG. 2, or to remove the adhesive portion 50 between the two adjacent semiconductor stacks 20 to form separated bodies B of the adhesive portion 50 (as shown in FIG. 1). A contour of the surface 34T’ of the second conductive layer 34 matches a contour of the surface 50T of the adhesive portion 50. In some embodiments, the second conductive layer 34 covers the second portion 22P2 of the protective layer 22 and the first conductive layer 32. In some embodiments, an adhesive force of the third portion 52 to the semiconductor device 36 is greater than an adhesive force of the fourth portion 54 to the semiconductor device 36. In some embodiments, the third portion 52 of the adhesive portion 50 contacts the first portion 22P1 of the protective layer 22, and the fourth portion 54 of the adhesive portion 50 contacts the second conductive layer 34. In some embodiments, the second conductive layer 34 has a first thickness t1’.

As shown in FIG. 7, in some embodiments, in a cross-sectional view, the second conductive layer 34 has an asymmetric structure along the first axis D20. In some embodiments, when viewed along the third direction D3, a projection of the first conductive layer 32 does not completely overlap a projection of the second conductive layer 34. In some embodiments, when viewed along the third direction D3, a projected area of the first conductive layer 32 may be smaller than, equal to, or greater than a projected area of the second conductive layer 34.

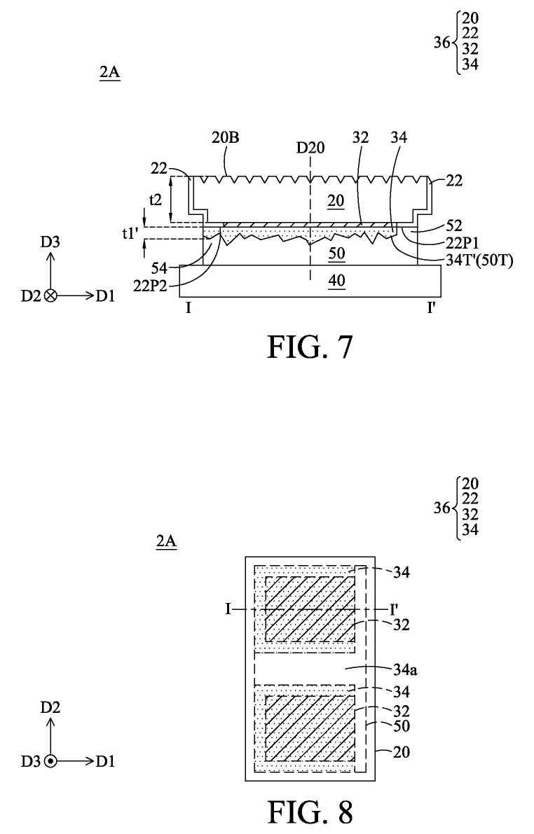

FIG. 8 shows a schematic top view of the semiconductor unit 2A shown in FIG. 7. In some embodiments, FIG. 7 is a schematic cross-sectional view taken along line I-I’ in FIG. 8. For simplicity, FIG. 8 only shows the first conductive layer 32, the second conductive layer 34, the carrier 40, and the adhesive portion 50 of the semiconductor unit 2A. As shown in FIG. 8, in some embodiments, a right-side portion of the adhesive portion 50 is exposed beyond the second conductive layer 34, and a left-side portion of the adhesive portion 50 overlaps the second conductive layer 34. In some embodiments, a right edge of the second conductive layer 34 is spaced apart from a right edge of the adhesive portion 50 by a distance. In some embodiments, the second conductive layer 34 is divided into an upper region and a lower region separated by an opening 34a.

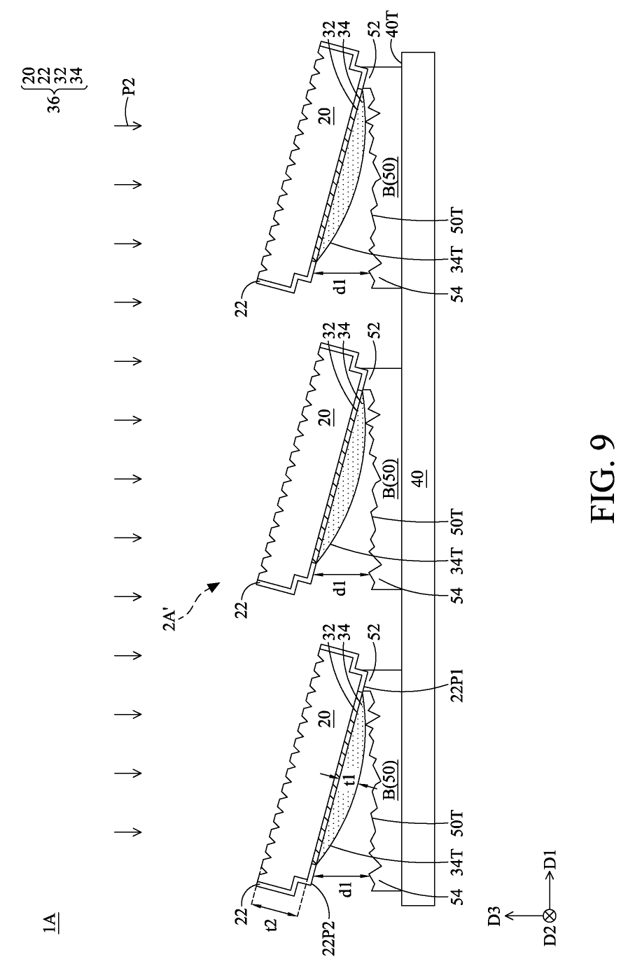

As shown in FIG. 9, an irradiation process P2 is performed on the semiconductor unit 2A shown in FIG. 7 to reshape the second conductive layer 34. The irradiation process P2 applies energy to the semiconductor unit 2A. Accordingly, the second conductive layer 34 having a lower melting point is reshaped. After the irradiation process P2, the first portion 22P1 of the protective layer 22 contacts the adhesive portion 50, and the second portion 22P2 of the protective layer 22 is spaced apart from the adhesive portion 50 by a distance d1. In some embodiments, the irradiation process P2 includes irradiating the semiconductor unit 2A with a laser, and the laser includes an infrared (IR) laser. In some embodiments, the laser is irradiated along a direction opposite to the third direction D3 to form the semiconductor unit 2A. In other embodiments, the laser is irradiated along the third direction D3 (not shown) to form the semiconductor unit 2A. In some embodiments, part of the laser passes through the carrier 40 and irradiates the second conductive layer 34. In other embodiments, the irradiation process P2 includes applying energy to the semiconductor unit 2A by using an oven. In some embodiments, the second conductive layer 34 has a greater affinity for the first conductive layer 32 than for the protective layer 22. After performing the irradiation process P2, the second conductive layer 34 tends to accumulate on the first conductive layer 32 and expose the protective layer 22. Accordingly, after the irradiation process P2, the second conductive layer 34 forms the protruding surface 34T protruding toward the adhesive portion 50. That is, the irradiation process P2 transforms the relatively rough surface 34T’ of the second conductive layer 34 (as shown in FIG. 7) into the relatively smooth protruding surface 34T (as shown in FIG. 9). Since the volume of the second conductive layer 34 remains substantially constant, the first thickness t1’ of the second conductive layer 34 before the irradiation process P2 (as shown in FIG. 7) is less than the first thickness t1 of the second conductive layer 34 after the irradiation process P2 (as shown in FIG. 9). In some embodiments, the energy provided by the irradiation process P2 does not affect (or damage) the first conductive layer 32, the protective layer 22, and the semiconductor stack 20, which have higher melting points. In some embodiments, the irradiation process P2 further includes using a limiter (not shown) to limit an angle of inclination of the semiconductor device 36 (e.g., the included angle a1 shown in FIG. 1). In some embodiments, the limiter is located above the semiconductor device 36 (not shown), and a bottom surface of the limiter is parallel to an upper surface of the carrier 40 (e.g., perpendicular to the third direction D3).

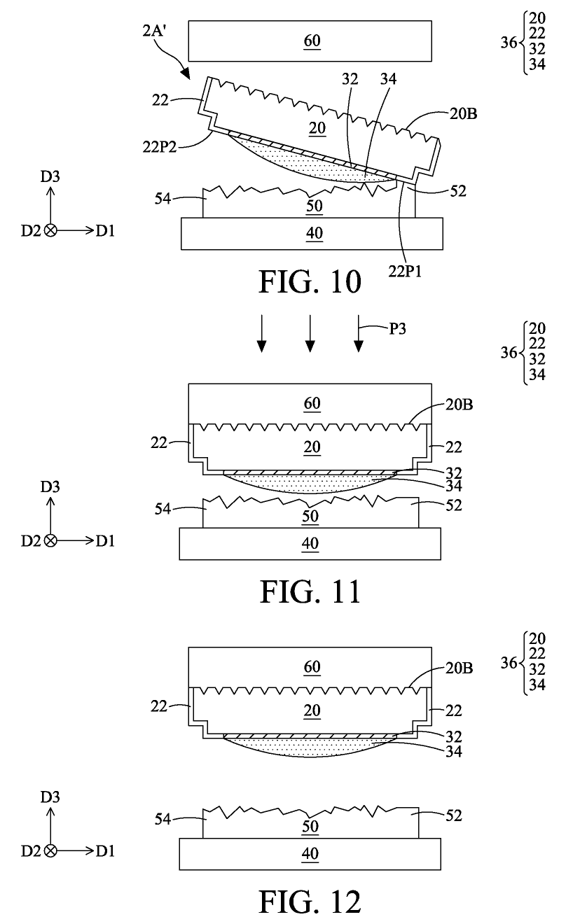

As shown in FIG. 10, in some embodiments, a transfer process is performed on the semiconductor device 36 by using a stamp 60. As shown in FIG. 11, a pressing process P3 is performed so that the stamp 60 is connected to the surface 20B of the semiconductor stack 20. In some embodiments, after the stamp 60 is pressed downward in a direction opposite to the third direction D3, the first portion 22P1 of the protective layer 22 is separated from the third portion 52 of the adhesive portion 50. In some embodiments, a lower surface of the stamp 60 is parallel to an upper surface of the carrier 40, and the pressing process P3 reduces an angle between the semiconductor device 36 and the carrier 40 (e.g., the included angle a1 shown in FIG. 1) to approximately 0 degrees. In other embodiments, a residue of the adhesive portion 50 remains on a bottom surface of the separated semiconductor device 36. As shown in FIG. 12, the stamp 60 can transfer the semiconductor device 36.

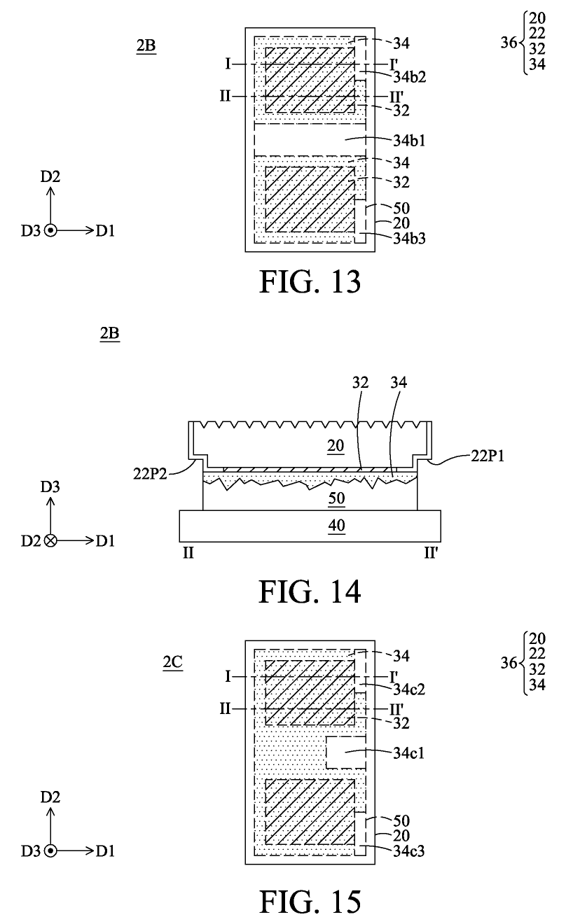

Referring to FIGS. 13 and 14, FIGS. 13 and 14 respectively show a schematic top view and a schematic cross-sectional view of a semiconductor unit 2B according to other embodiments of the present disclosure. In some embodiments, FIG. 7 shows a schematic cross-sectional view taken along line I-I’ shown in FIG. 13, and FIG. 14 shows a schematic cross-sectional view taken along line II-II’ shown in FIG. 13. In some embodiments, a portion of a right edge of the second conductive layer 34 of the semiconductor unit 2B is spaced apart from a right edge of the adhesive portion 50 by a distance (as shown in FIG. 7), and another portion of the right edge of the second conductive layer 34 is flush with the right edge of the adhesive portion 50 (as shown in FIG. 14). In some embodiments, the second conductive layer 34 has a plurality of openings 34b1, 34b2, and 34b3, and the plurality of openings 34b1, 34b2, and 34b3 is disconnected from one another. In some embodiments, the openings 34b2 and 34b3 are located at corners of the semiconductor unit 2B. As shown in FIG. 14, in some embodiments, the second conductive layer 34 is located between the adhesive portion 50 and the protective layer 22, and between the adhesive portion 50 and the first conductive layer 32. In other words, in the semiconductor unit 2B, at least a portion of the second conductive layer 34 extends between the first portion 22P1 of the protective layer 22 and the adhesive portion 50. After the irradiation process P2 is performed on the semiconductor unit 2B, the semiconductor device array structure 1A shown in FIG. 1 may be formed.

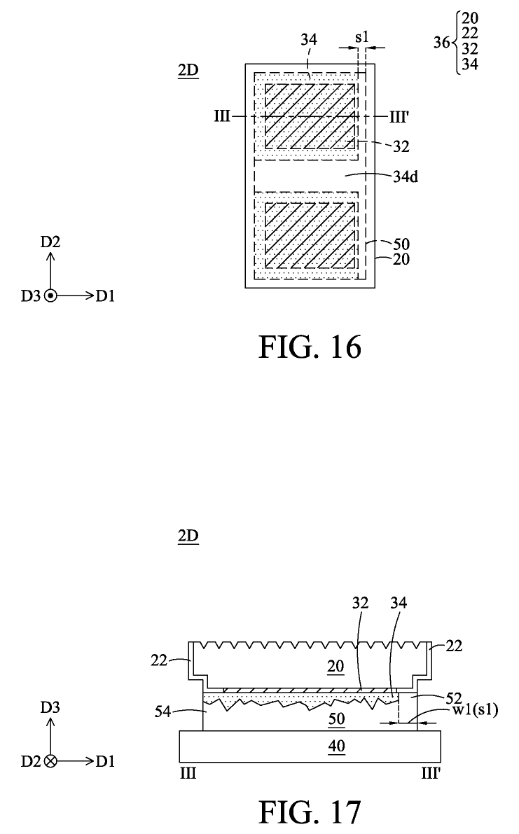

Referring to FIG. 15, FIG. 15 shows a schematic top view of a semiconductor unit 2C according to still other embodiments of the present disclosure. In some embodiments, FIG. 7 shows a schematic cross-sectional view taken along line I-I’ shown in FIG. 15, and FIG. 14 shows a schematic cross-sectional view taken along line II-II’ shown in FIG. 15. As shown in FIG. 15, the second conductive layer 34 of the semiconductor unit 2C is a continuous structure and has a plurality of openings 34c1, 34c2, and 34c3. The plurality of openings 34c1, 34c2, and 34c3 is disconnected from one another and do not divide the second conductive layer 34 into a plurality of blocks. In some embodiments, after the irradiation process P2 is performed on the semiconductor unit 2C, the semiconductor unit 2A’ shown in FIG. 1 may be formed.

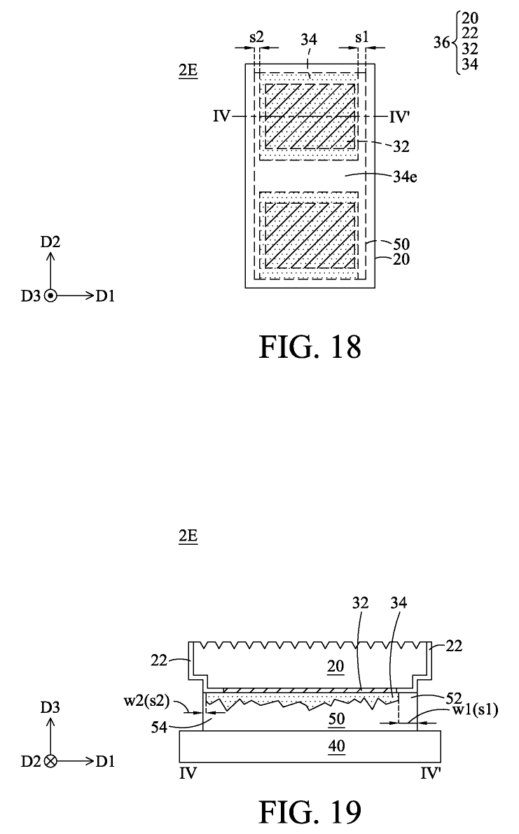

Referring to FIGS. 16 and 17, FIGS. 16 and 17 respectively show a schematic top view and a schematic cross-sectional view of a semiconductor unit 2D according to still other embodiments of the present disclosure. In some embodiments, FIG. 17 shows a schematic cross-sectional view taken along line III-III’ shown in FIG. 16. As shown in FIGS. 16 and 17, in the semiconductor unit 2D, a right edge of the second conductive layer 34 extends beyond a right edge of the first conductive layer 32 and is spaced apart from a right edge of the adhesive portion 50 by a distance s1. As shown in FIG. 17, the third portion 52 of the adhesive portion 50 has a first width w1 corresponding to the distance s1. After the irradiation process P2 is performed on the semiconductor unit 2D, the semiconductor unit 2A’ shown in FIG. 1 may be formed.

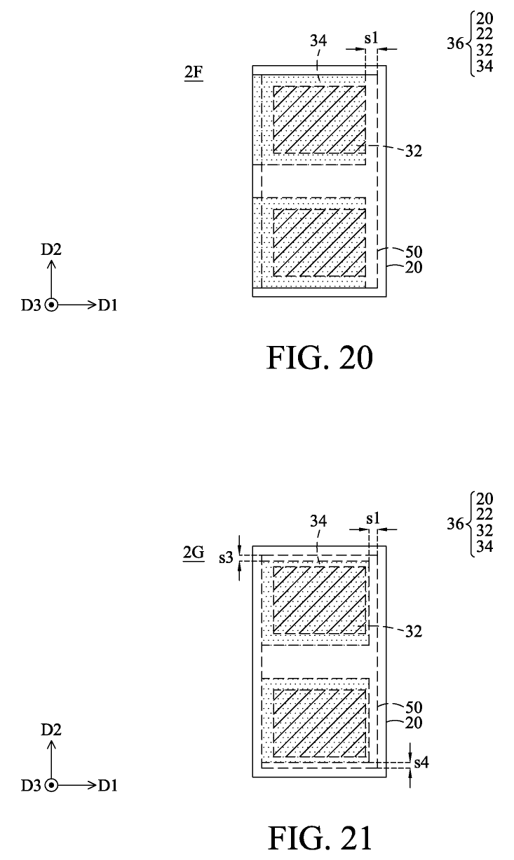

Referring to FIGS. 18 and 19, FIG. 18 and 19 respectively show a schematic top view and a schematic cross-sectional view of a semiconductor unit 2E according to still other embodiments of the present disclosure, in which FIG. 19 shows a schematic cross-sectional view taken along line IV-IV’ shown in FIG. 18. As shown in FIG. 18, in some embodiments, the second conductive layer 34 has an opening 34e, and the opening 34e divides the second conductive layer 34 into upper and lower regions. In some embodiments, a right edge of the second conductive layer 34 is spaced apart from a right edge of the adhesive portion 50 by a distance s1, and a left edge of the second conductive layer 34 is spaced apart from a left edge of the adhesive portion 50 by a distance s2. As shown in FIG. 19, in some embodiments, the third portion 52 of the adhesive portion 50 has a first width w1 corresponding to the distance s1, the fourth portion 54 of the adhesive portion 50 has a second width w2 corresponding to the distance s2, and the first width w1 is greater than the second width w2. Since a contact area between the third portion 52 and the protective layer 22 is different from a contact area between the fourth portion 54 and the protective layer 22, an adhesive force of the third portion 52 on the protective layer 22 is greater than an adhesive force of the fourth portion 54 on the protective layer 22. In some embodiments, the third portion 52 and the fourth portion 54 contact the protective layer 22, and the second conductive layer 34 contacts the protective layer 22 and the first conductive layer 32. After the irradiation process P2 is performed on the semiconductor unit 2E, the semiconductor device array structure 1A shown in FIG. 1 may be formed.

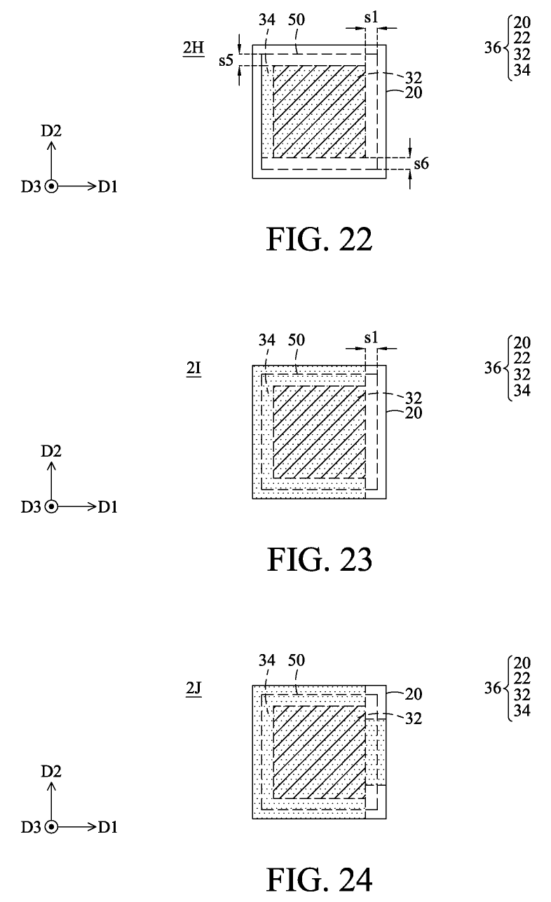

Referring to FIG. 20, FIG. 20 shows a schematic top view of a semiconductor unit 2F according to different embodiments of the present disclosure. In some embodiments, a right edge of the second conductive layer 34 of the semiconductor unit 2F is spaced apart from a right edge of the adhesive portion 50 by a distance s1. A left edge of the second conductive layer 34 of the semiconductor unit 2F extends beyond a left edge of the adhesive portion 50 and is flush with the left edge of the semiconductor stack 20. After the irradiation process P2 is performed on the semiconductor unit 2F, the semiconductor device array structure 1A shown in FIG. 1 may be formed.

Referring to FIG. 21, FIG. 21 shows a schematic top view of a semiconductor unit 2G according to different embodiments of the present disclosure. In some embodiments, a right edge of the second conductive layer 34 of the semiconductor unit 2G is spaced apart from a right edge of the adhesive portion 50 by a distance s1, and a left edge of the second conductive layer 34 is flush with a left edge of the adhesive portion 50. An upper edge of the second conductive layer 34 is spaced apart from an upper edge of the adhesive portion 50 by a distance s3, and a lower edge of the second conductive layer 34 is spaced apart from a lower edge of the adhesive portion 50 by a distance s4, where the distance s3 and the distance s4 may be the same as or different from each other. After the irradiation process P2 is performed on the semiconductor unit 2G, the semiconductor device array structure 1A shown in FIG. 1 may be formed.

Referring to FIGS. 22 to 27, FIGS. 22 to 27 show schematic top views of semiconductor units 2H-2M according to different embodiments of the present disclosure. In other embodiments, the semiconductor device 36 is a vertical chip. Two electrodes having different polarities are located on opposite sides of the semiconductor stack 20, and the second conductive layer 34 is connected to one of the two electrodes.

As shown in FIG. 22, in some embodiments, a right edge of the second conductive layer 34 of the semiconductor unit 2H is spaced apart from a right edge of the adhesive portion 50 by a distance s1, and a left edge of the second conductive layer 34 is flush with a left edge of the adhesive portion 50. In some embodiments, an upper edge of the second conductive layer 34 is spaced apart from an upper edge of the adhesive portion 50 by a distance s5, and the upper edge of the second conductive layer 34 is flush with an upper edge of the first conductive layer 32. In some embodiments, a lower edge of the second conductive layer 34 is spaced apart from a lower edge of the adhesive portion 50 by a distance s6, and the lower edge of the second conductive layer 34 is flush with a lower edge of the first conductive layer 32.

As shown in FIG. 23, in some embodiments, a right edge of the second conductive layer 34 of the semiconductor unit 2I is spaced apart from a right edge of the adhesive portion 50 by a distance s1, and a left edge of the second conductive layer 34 is flush with a left edge of the semiconductor stack 20. In some embodiments, an upper edge of the second conductive layer 34 is flush with an upper edge of the semiconductor stack 20, and a lower edge of the second conductive layer 34 is flush with a lower edge of the semiconductor stack 20.

As shown in FIG. 24, in some embodiments, the second conductive layer 34 of the semiconductor unit 2J has an opening, and the opening is located at a right corner of the semiconductor device. A portion of a right edge of the second conductive layer 34 of the semiconductor unit 2J is flush with a right edge of the semiconductor stack 20.

As shown in FIG. 25, in some embodiments, a right edge of the second conductive layer 34 of the semiconductor unit 2K is spaced apart from a right edge of the adhesive portion 50 by a distance s1, and a lower edge of the second conductive layer 34 is spaced apart from a lower edge of the adhesive portion 50 by a distance s6. In some embodiments, the distance s1 may be the same as or different from the distance s6. In some embodiments, after the irradiation process P2 is performed on the semiconductor unit 2K, two side edges of the adhesive portion 50 (i.e., the right edge and the lower edge) contact the protective layer 22 (e.g., the third portion 52 shown in FIG. 1 contacts the protective layer), and other side edges of the adhesive portion 50 (i.e., the left edge and the upper edge) are separated from the protective layer 22 (e.g., the fourth portion 54 shown in FIG. 1 is separated from the protective layer 22).

As shown in FIG. 26, in some embodiments, a right edge of the second conductive layer 34 of the semiconductor unit 2L is spaced apart from a right edge of the adhesive portion 50 by a distance s1, and the right edge of the second conductive layer 34 extends beyond a right edge of the first conductive layer 32. In some embodiments, a lower edge of the second conductive layer 34 is spaced apart from a lower edge of the adhesive portion 50 by a distance s6, and the lower edge of the second conductive layer 34 extends beyond a lower edge of the first conductive layer 32. In some embodiments, the distance s1 may be the same as or different from the distance s6.

As shown in FIG. 27, in some embodiments, the second conductive layer 34 of the semiconductor unit 2M has an opening located at a corner of the semiconductor stack 20. A portion of a right edge of the second conductive layer 34 is flush with a right edge of the semiconductor stack 20, and a portion of a lower edge of the second conductive layer 34 is flush with a lower edge of the carrier 40.

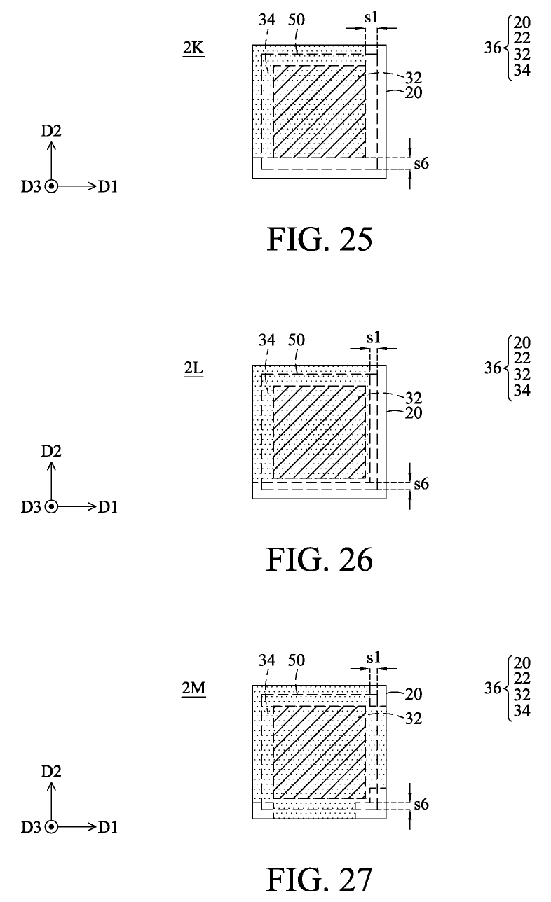

Referring to FIGS. 28 and 29, FIGS. 28 and 29 respectively show a schematic top view and a schematic cross-sectional view of a semiconductor unit 2N according to still other embodiments of the present disclosure. In some embodiments, FIG. 29 shows a schematic cross-sectional view taken along line V-V’ shown in FIG. 28. As shown in FIG. 28, a right edge of the second conductive layer 34 is spaced apart from a right edge of the first conductive layer 32 by a distance s7, and a lower edge of the second conductive layer 34 is spaced apart from a lower edge of the first conductive layer 32 by a distance s8. As shown in FIG. 29, in some embodiments, the second conductive layer 34 exposes a portion of the first conductive layer 32, and a third portion 52 of the adhesive portion 50 contacts the first conductive layer 32 and the protective layer 22.

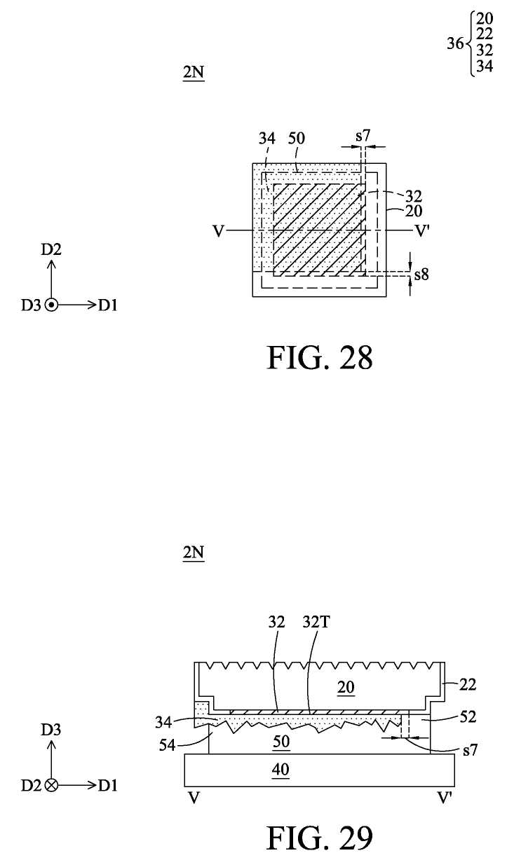

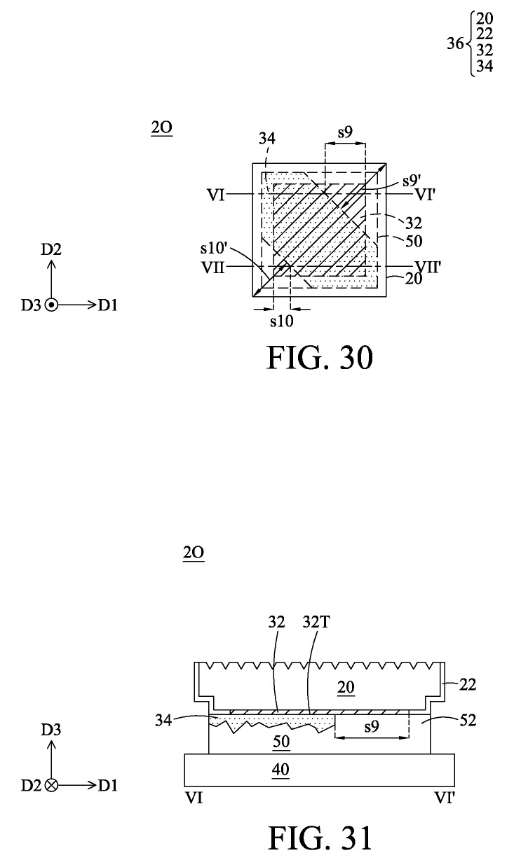

Referring to FIGS. 30 to 32, FIG. 30 shows a schematic top view of a semiconductor unit 2O according to still other embodiments of the present disclosure, and FIGS. 31 and 32 shows schematic cross-sectional views of the semiconductor unit 2O according to still other embodiments of the present disclosure. In some embodiments.

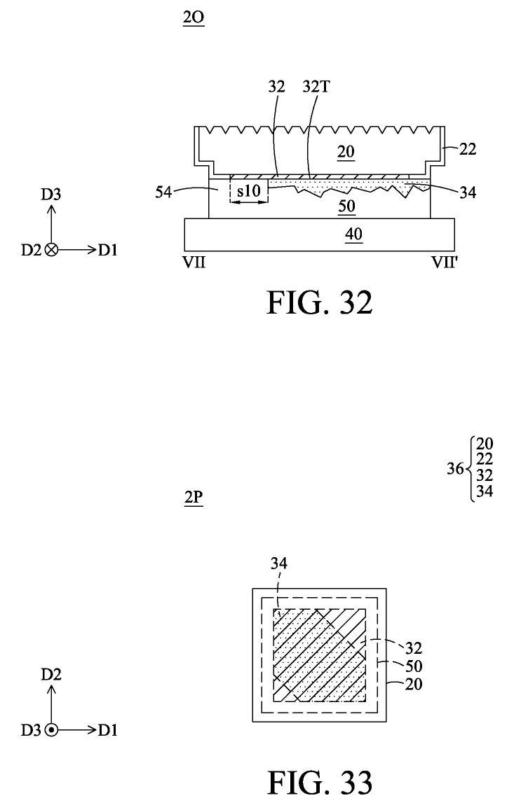

Referring to FIG. 33, FIG. 33 shows a schematic top view of a semiconductor unit 2P according to still other embodiments of the present disclosure. As shown in FIG. 33, in some embodiments, FIG. 31 shows a schematic cross-sectional view taken along line VI-VI’ shown in FIGS. 30 and 32 shows a schematic cross-sectional view taken along line VII-VII’ shown in FIG. 30. In some embodiments, a right edge of the second conductive layer 34 is spaced apart from a right edge of the first conductive layer 32 by a distance s9, a left edge of the second conductive layer 34 is spaced apart from a left edge of the first conductive layer 32 by a distance s10, and the distance s10 is less than the distance s9. As shown in FIG. 30, in some embodiments, a right edge of the second conductive layer 34 is spaced apart from an upper right corner of the semiconductor stack 20 by a distance s9’, a left edge of the second conductive layer 34 is spaced apart from a lower left corner of the semiconductor stack 20 by a distance s10’, and the distance s9’ is greater than the distance s10’.

In some embodiments, other details of the semiconductor units 2B-2P may be referred to the related paragraphs describing the semiconductor unit 2A, and the semiconductor units 2B-2P may form the semiconductor unit 2A’ shown in FIG. 9 after the irradiation process P2. In other embodiments, the semiconductor device array structure 1A or 1A’ shown in FIGS. 1 or 2 is formed by subjecting at least one or more of the semiconductor units 2A-2P to the irradiation process P2.

In conclusion, the present disclosure improves the reliability of a mass transfer process of semiconductor devices by adjusting a relative relationship between an adhesive portion and a semiconductor device, such as an arrangement position or a process sequence. For example, by performing a curing process before performing an irradiation process, the adhesive portion is brought into contact with a first portion of the semiconductor device, and the adhesive portion is separated from a second portion of the semiconductor device. Accordingly, a pick-up rate of the semiconductor devices in the mass transfer process is improved, a drop rate of the semiconductor devices is reduced, and/or a flipping rate of the semiconductor devices is reduced. For example, by adjusting arrangement positions among a first conductive layer and a second conductive layer of the semiconductor device, the adhesive portion, and a carrier, sizes of the first portion and the second portion, a warpage angle of the semiconductor device, and the like are adjusted, thereby adjusting adhesive forces of the adhesive portion on different portions of the semiconductor device. Accordingly, the semiconductor device array structure of the present disclosure may be widely applied to different transfer processes.

Although the present disclosure has been described in considerable detail with reference to certain embodiments thereof, the disclosure is not for limiting the scope of the invention. Persons having ordinary skill in the art may make various modifications and changes without departing from the scope and spirit of the disclosure. Therefore, the scope of protection of the present disclosure shall be defined by the appended claims.

What is claimed is:

1. A semiconductor device arrangement, comprising:
a carrier having a first surface;
an adhesive portion disposed on the first surface; and
a semiconductor device disposed on the adhesive portion and having a second surface;
wherein the first surface has a first normal, the second surface has a second normal, and an included angle between the first normal and the second normal is greater than 5 degrees and less than 45 degrees.

2. The semiconductor device arrangement according to claim 1, wherein the semiconductor device comprises a semiconductor stack with a side surface and a protective layer, and the protective layer covers the side surface of the semiconductor stack.

3. The semiconductor device arrangement according to claim 2, wherein the protective layer comprises a first portion and a second portion, the adhesive portion comprises a third portion and a fourth portion, and the first portion contacts the third portion.

4. The semiconductor device arrangement according to claim 3, wherein the semiconductor device further comprises a first conductive layer and a second conductive layer, the first conductive layer is connected to the semiconductor stack, and the second conductive layer covers the first conductive layer.

5. The semiconductor device arrangement according to claim 4, wherein the second conductive layer directly contacts the adhesive portion.

6. The semiconductor device arrangement according to claim 4, wherein the second conductive layer comprises a protruding surface protruding toward the adhesive portion.

7. The semiconductor device arrangement according to claim 6, wherein the adhesive portion comprises a third surface, the protruding surface comprises a first roughness, the third surface comprises a second roughness, and the first roughness is less than the second roughness.

8. The semiconductor device arrangement according to claim 4, wherein the first conductive layer comprises a first melting point, the second conductive layer comprises a second melting point, and the second melting point is less than the first melting point.

9. The semiconductor device arrangement according to claim 4, wherein the semiconductor stack comprises a first thickness, the second conductive layer comprises a second thickness, and the second thickness is less than or equal to the first thickness.

10. The semiconductor device arrangement according to claim 4, wherein, in a cross-sectional view, the first conductive layer is located between the first portion and the second portion.

11. A semiconductor device arrangement, comprising:
a carrier having a first surface;
an adhesive portion disposed on the first surface;
a plurality of semiconductor devices disposed on the adhesive portion, wherein each of the plurality of semiconductor devices comprises a second surface; and
a plurality of connecting portions disposed on the first surface, wherein each of the plurality of connecting portions is located between two adjacent ones of the plurality of semiconductor devices;
wherein the first surface has a first normal, the second surface has a second normal, and an included angle between the first normal and the second normal is greater than 5 degrees and less than 45 degrees.

12. The semiconductor device arrangement according to claim 11, wherein each of the plurality of semiconductor devices comprises a semiconductor stack with a side surface and a protective layer, and the protective layer covers the side surface of the semiconductor stack.

13. The semiconductor device arrangement according to claim 12, wherein the protective layer comprises a first portion and a second portion, the adhesive portion comprises a third portion and a fourth portion, and the first portion contacts the third portion.

14. The semiconductor device arrangement according to claim 13, wherein each of the plurality of semiconductor devices further comprises a first conductive layer and a second conductive layer, the first conductive layer is connected to the semiconductor stack, and the second conductive layer covers the first conductive layer.

15. The semiconductor device arrangement according to claim 14, wherein the second conductive layer directly contacts the adhesive portion.

16. The semiconductor device arrangement according to claim 14, wherein the second conductive layer comprises a protruding surface protruding toward the adhesive portion.

17. The semiconductor device arrangement according to claim 16, wherein the adhesive portion comprises a third surface, the protruding surface comprises a first roughness, the third surface comprises a second roughness, and the first roughness is less than the second roughness.

18. The semiconductor device arrangement according to claim 14, wherein the first conductive layer comprises a first melting point, the second conductive layer comprises a second melting point, and the second melting point is less than the first melting point.

19. The semiconductor device arrangement according to claim 14, wherein the semiconductor stack comprises a first thickness, the second conductive layer comprises a second thickness, and the second thickness is less than or equal to the first thickness.

20. The semiconductor device arrangement according to claim 14, wherein in a cross-sectional view, the first conductive layer is located between the first portion and the second portion.
